(19) United States
(12) Patent Application Publication
(10) Pub. No.: US 2008/0158809 A1
(43) Pub. Date: Jul. 3, 2008

(54) COMPUTER ENCLOSURE INCORPORATING DRIVE BRACKET

(75) Inventors: Yun-Lung Chen, Tu-Cheng (TW); Qing-Hao Wu, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/752,311

(22) Filed: May 23, 2007

(30) Foreign Application Priority Data
Dec. 29, 2006 (CN) 200620145400.2

(51) Int. Cl. H05K 7/00

(52) U.S. Cl. 361/685

(57) ABSTRACT

A computer enclosure includes a cage (30), a drive bracket (20) pivotably mounted to the cage, a damper device (24) including a base (240) secured to the drive bracket and a damper gear (241) being rotatable relative to the base when an external force is exerted thereon and being held relative to the base by a resisting force formed therebetween when the external force is withdrawn, and an engaging member (33) attached to the cage including a plurality of teeth (3311) meshed with the damper gear of the damper device. The drive bracket is capable of being held in any position during rotation thereof by the resisting force between the damper gear and the base resisting rotation.

### BACKGROUND OF THE INVENTION

1. Field of the Invention

The present invention relates to computer enclosures, and more particularly to a computer enclosure incorporating a pivitable drive bracket.

2. Description of Related Art

Various data storage devices are installed in computers for communication and handling of data. Such devices include, for example, hard disk drives, floppy disk drives, and CD-ROM drives.

In a conventional computer, a data storage device is attached in a drive bracket. The combined drive bracket with data storage device is then attached to a computer enclosure. The drive bracket is secured to the computer enclosure with screws. However, many components are compactly arranged in a limited space inside the computer enclosure. It is hard to remove these date storage devices when they need to be replaced or repaired.

Therefore, a pivotable drive bracket has been developed. The drive bracket has circular pivots on opposite sides thereof. The computer provides circular holes in a front panel thereof. The pivots can rotate in the holes to pivotably attach the storage device to the computer enclosure. However, no locating components are available to maintain the bracket after the bracket is rotated, and therefore an operator must hold the drive bracket with one hand while removing the data storage device with the other.

What is needed, therefore, is to provide a computer enclosure incorporating a drive bracket, that can be pivotably installed and locatable in any position during rotation thereof.

### SUMMARY OF THE INVENTION

A computer enclosure comprises a cage, a drive bracket pivotably mounted to the cage, a damper device comprising a base secured to the drive bracket and a damper gear being rotatable relative to the base when an external force is exerted thereon and being hold relative to the base by a resisting force formed therebetween when the external force is withdrawn, and an engaging member attached to the cage including a plurality of teeth meshed with the damper gear of the damper device. The drive bracket is capable of being held in any position during rotation thereof by the resisting force between the damper gear and the base resisting rotation.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a computer enclosure in accordance with a preferred embodiment of the present invention;

FIG. 2 is an isometric view of a drive bracket in accordance with a preferred embodiment of the present invention;

FIG. 3 is an assembled view of FIG. 1, showing the drive bracket rotated to an inclined position;

FIG. 4 is an assembled view of FIG. 1, showing the drive bracket rotated to a horizontal position; and

FIG. 5 is similar to FIG. 4, but viewed from another aspect.

### DETAILED DESCRIPTION OF THE INVENTION

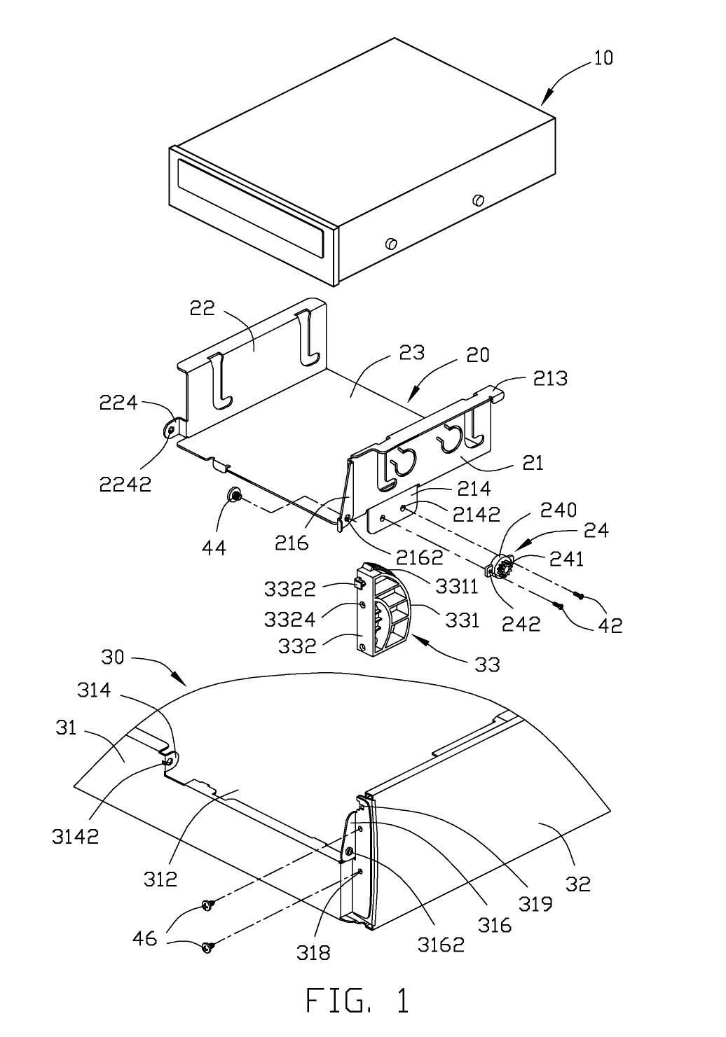

Referring to FIG. 1, a computer enclosure in accordance with the preferred embodiment of the present invention includes a cage 30, a drive bracket 20 for securing a disk drive 10, a damper device 24, and an engaging member 33.

The cage 30 includes a front plate 31 and a side plate 32 vertical to the front plate 31. The front plate 31 defines an opening 312 therein for receiving the drive bracket 20. A tab 314 with a pivot hole 3142 extends backwards from a side edge of the opening 312. A tab 316 with a screw hole 3162 extends forwards from the other side edge of the opening 312. The front plate 31 defines a pair of screw holes 318 and a securing cutout 319 in a right side of the opening 312.

The damper device 24 comprises a base 240 and a damper gear 241. The damper gear 241 is rotatable relative to the base 240 when an external force is exerted thereon and can be held at a current position when the external force is withdrawn due to friction between the damper gear 241 and the base 240. Each side portion of the base 240 defines a screw hole 242 therein. The engaging member 33 comprises an arcuate surface 331 with a plurality of teeth 3311 formed thereon, which is configured for meshing with the damper gear 241 of the damper device 24, and a securing portion 332. The securing portion 332 defines a pair of screw holes 3324 therein. A latching protrusion 3322 with a slim portion in the middle thereof is formed on the securing portion 332 configured for engaging with the securing cutout 319 of the cage 30.

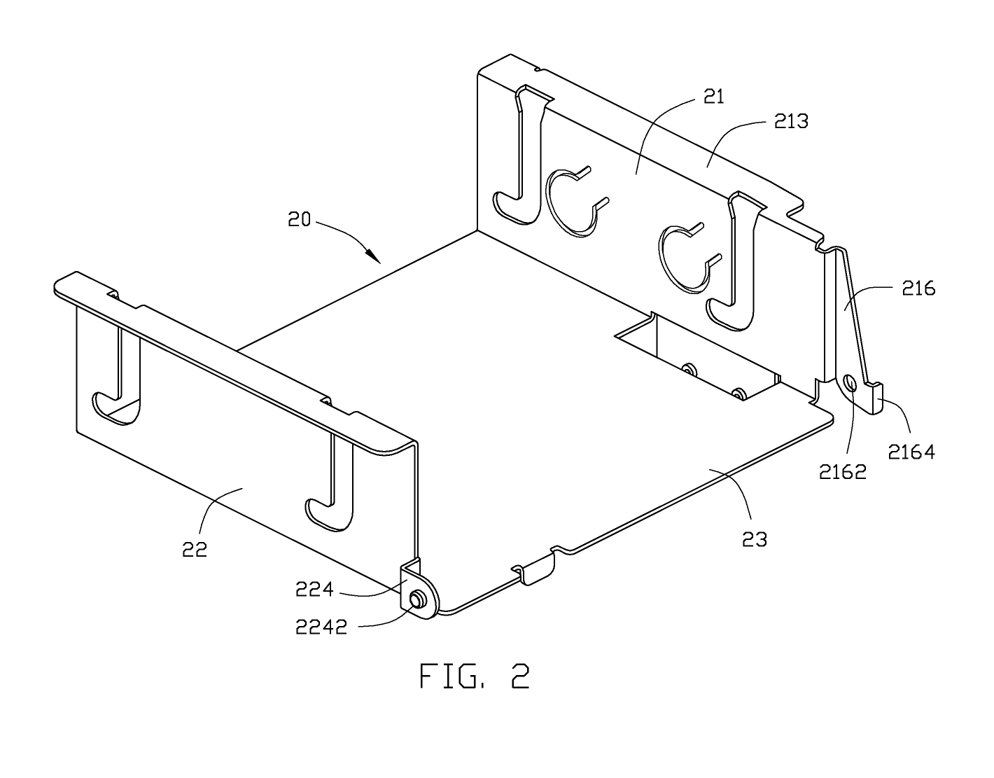

Referring to FIGS. 1 and 2, the drive bracket 20 includes a bottom panel 23 and a pair of side panels 21, 22 extending perpendicularly from opposite edges of the bottom panel 23. A tab 216 extends forwards from a front edge of the side panel 21. The tab 216 defines a through hole 2162 therein corresponding to the screw hole 3162 of the tab 316. An assembly tab 214 extends downwards from a down edge of the side panel 21. The assembly tab 214 defines a pair of assembly holes 2142 corresponding to the screw holes 242 of the damper device 24. A resisting tab 213 extends outwards from an upper edge of the side panel 21. A tab 224 with a pivot 2242 for pivoting in the pivot hole 3142 of the tab 314 extends forwards from a front edge of the side panel 22.

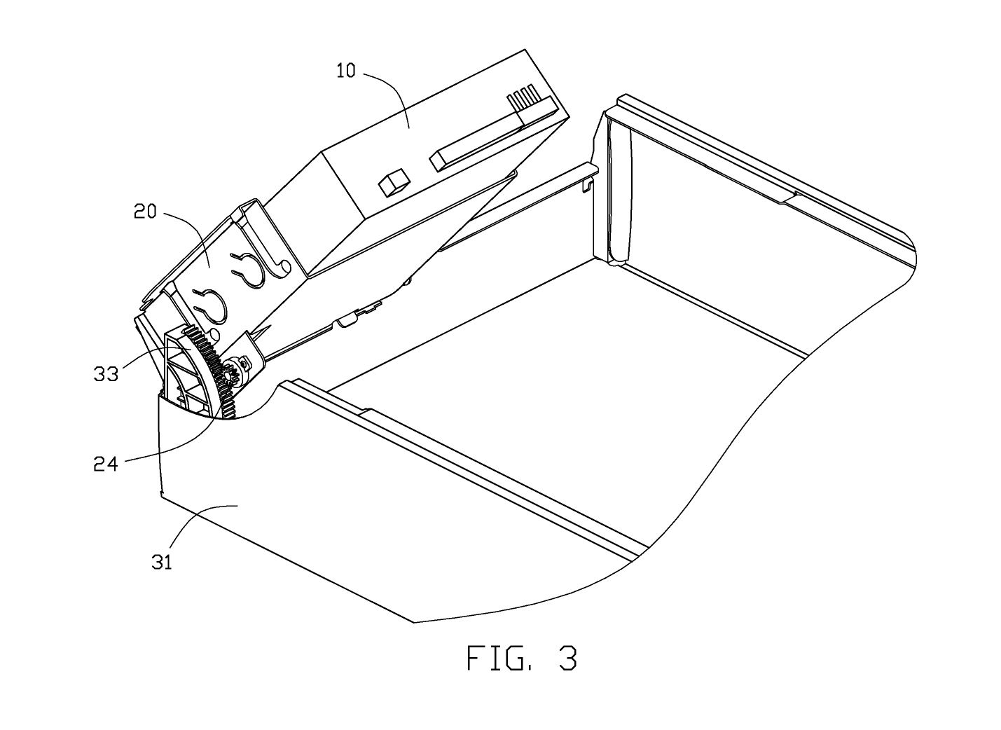

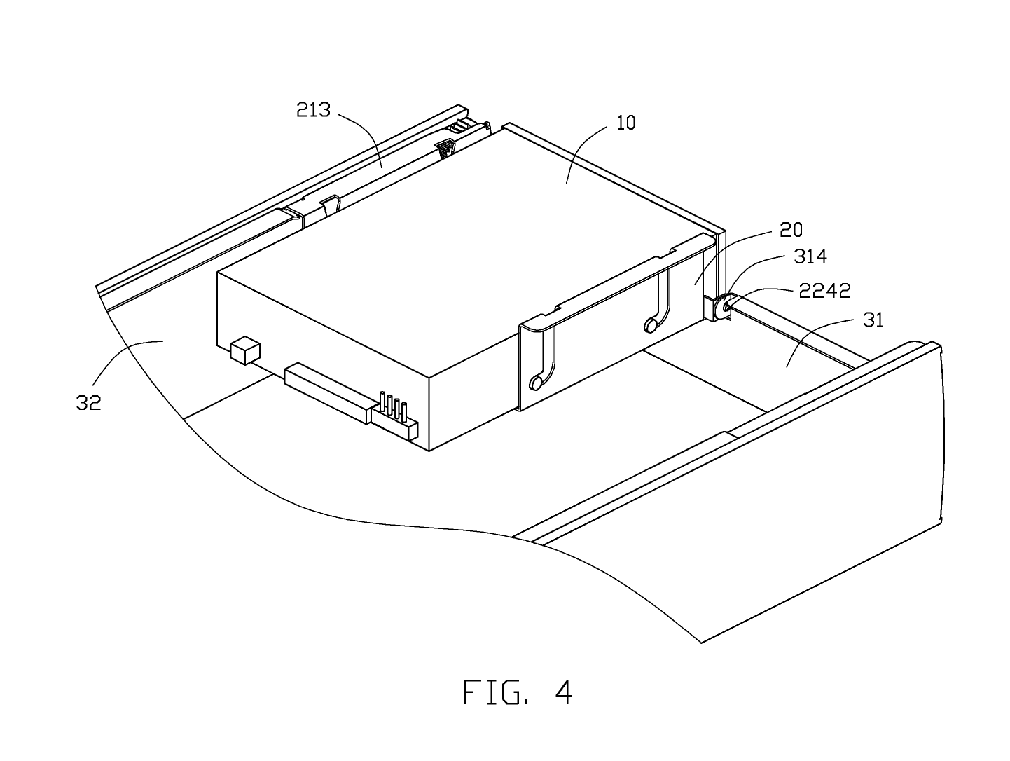

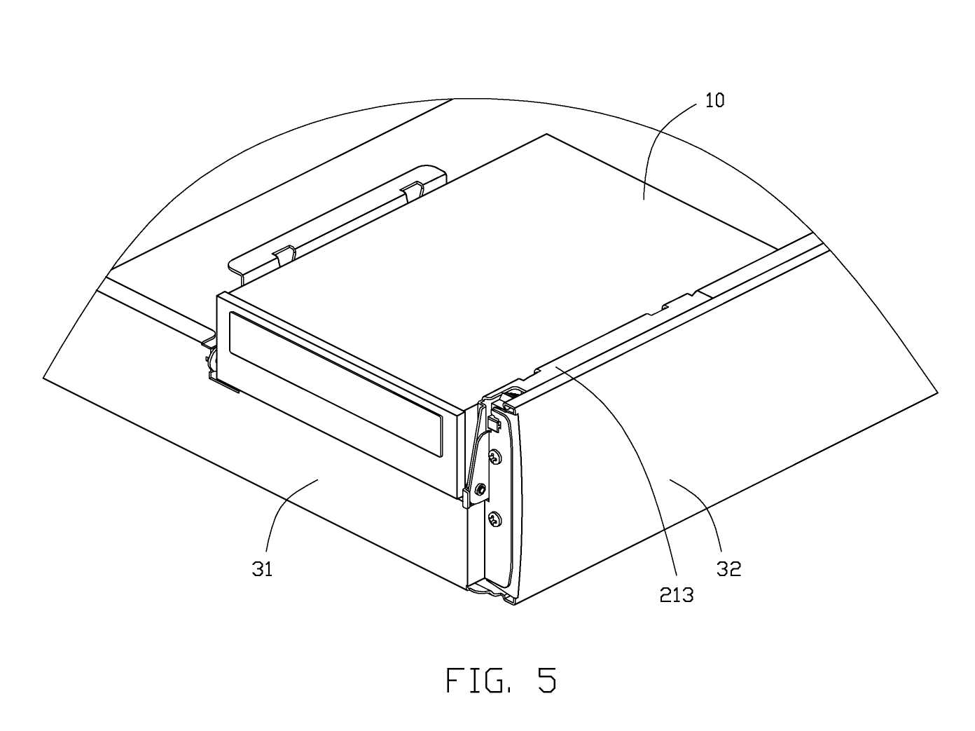

Referring also to FIGS. 3 to 5, in assembling the drive bracket 20 into the cage 30, the engaging member 33 is placed on an inner surface of the side plate 32 and abuts on the front plate 31. The slim portion of latching protrusion 3322 is inserted into the securing cutout 319. The screw holes 3324 of the engaging member 33 align with the corresponding screw holes 318 of the front plate 31. A pair of screws 46 is extended through the corresponding screw holes 318 of the cage 30 to engage in the screw holes 3324 of the engaging member 33, thereby securing the engaging member 33 to the cage 30. A pair of screws 42 is extended through the screw holes 242 of the damper device 24 to engage in the corresponding screw holes 2142 of the drive bracket 20 to secure the damper device 24 to the drive bracket 20. The pivot 2242 of the drive bracket 20 is inserted into the pivot hole 3142 of the cage 30 and a screw 44 is extended into both the through hole 2162 and the screw hole 3162, thereby pivotably mounting the drive bracket 20 to the cage 30. The damper gear 241 of the damper device 24 engagingly meshes with the teeth 3311 of the engaging member 33. When the drive bracket 20 rotates relative to the cage 30, the teeth of the damper device 24 roll between the teeth of the engaging member 30. When the drive bracket 20 rotates to a horizontal position, the resisting tab 213 of the drive bracket 20 resists against the upper edge of the side plate 32 of the cage 30, as shown in FIGS. 4 and 5.

When the computer needs checking, operators needn't remove the drive bracket 20 from the cage. The drive bracket 20 can be rotated to a suitable position corresponding to the cage 30. The damper gear 241 of the damper device 24 is engagingly meshed with the teeth 3311 of the engaging member 33, which enables the drive bracket 20 to be locatable in the suitable position convenient for operators checking the computer, as best shown in FIG. 3.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer enclosure, comprising:
a cage;
a drive bracket pivotably mounted to the cage;
a damper device including a base secured to the drive bracket and a damper gear being rotatable relative to the base when an external force is exerted thereon and being hold relative to the base by a resisting force formed therebetween when the external force is withdrawn; and
an engaging member attached to the cage including a plurality of teeth meshed with the damper gear of the damper device, wherein
the drive bracket is capable of being held in any position during rotation thereof by the resisting force between the damper gear and the base resisting rotation.

2. The computer enclosure as described in claim 1, wherein a side portion of the drive bracket forms a pivot, and the cage defines a pivot hole corresponding to the pivot.

3. The computer enclosure as described in claim 2, wherein the cage comprises a front plate with an opening configured for exposing the drive bracket, a tab extends from a side portion of the front plate communicating the opening, the pivot hole is defined in the tab, and the drive bracket comprises a pair of side panels one of which forms the pivot thereon.

4. The computer enclosure as described in claim 3, wherein a tab extends forward from the other side panel of the drive bracket, the tab defining a through hole thereof, and the front plate of the computer enclosure defines a corresponding screw hole.

5. The computer enclosure as described in claim 3, wherein a mounting tab extends downward from the other side panel of the drive bracket, the base of the damper device being secured to the mounting tab.

6. The computer enclosure as described in claim 3, wherein the cage comprises a side plate, and a resisting tab extends outwards from an upper edge of the other side panel which can resist on the upper edge of the side plate.

7. The computer enclosure as described in claim 1, wherein the engaging member defines a securing portion comprising a latching protrusion with a slim portion in the middle thereof and the cage defines a cutout corresponding to the slim portion of the latching protrusion.

8. The computer enclosure as described in claim 1, wherein the engaging member defines an arcuate surface which defines the plurality of teeth engaged with the damper gear of the damper device.

9. A positioning apparatus for positioning a drive bracket in a cage, comprising:
a damper device including a base secured to the drive bracket and a damper gear being rotatable relative to the base when an external force is exerted thereon and being hold relative to the base by a resisting force formed therebetween when the external force is withdrawn; and
an engaging member attached to the cage including a plurality of teeth meshed with the damper gear of the damper device, wherein
the resisting force between the damper gear and the base enables the drive bracket capable of being held in any position during rotation thereof.

10. The positioning apparatus as described in claim 9, wherein the engaging member comprises a latching protrusion with a slim portion in the middle thereof configured for engaging in a cutout of the cage.

11. The positioning apparatus as described in claim 9, wherein the engaging member defines an arcuate surface which defines a plurality of teeth engaged with the damper gear of the damper device.

12. A computer enclosure comprising:
a cage comprising a first plate and a second plate perpendicularly connected with the first plate, the first plate defining an opening;
a bracket configured for receiving a data storage device therein, the bracket comprising a pair of side panels pivotably attached to the cage at opposite sides of the opening so that the data storage device is movable through the opening;
an engaging member attached to the cage adjacent the second plate, the engaging member including an arcuate surface on which a plurality of teeth is formed; and
a damper device comprising a base fixed to the drive bracket and a damper gear meshed with the teeth of the engaging member, the damper gear being rotatable relative to the base when an external force is exerted thereon and being held relative to the base by a resisting force formed therebetween when the external force is withdrawn,
wherein when an external force is exerted on the bracket, the bracket is capable of pivoting relative to the cage together with the damper gear rotating along the teeth of the engaging member, and when the external force is withdrawn the bracket is capable of being held relative to the cage by the resisting force.

13. The computer enclosure as described in claim 12, wherein the bracket is pivotable relative to the cage about an axis perpendicular to the second plate.

14. The computer enclosure as described in claim 13, wherein the bracket comprises a tab extending from one of the side panels adjacent the second plate, the base of the damper device is attached to the tab and the damper gear is rotatable relative to the base about another axis perpendicular to the second plate.

15. The computer enclosure as described in claim 12, wherein the first plate forms at opposite sides of the opening a pair of tabs parallel to the second plate, the side panels of the bracket being pivotably attached to the tabs respectively.

16. The computer enclosure as described in claim 15, wherein one of the tabs defines a screw hole, one of the side panels defines a through hole, a screw extends through the through hole to engage in the screw hole.

17. The computer enclosure as described in claim 16, wherein the other one of the tabs defines a pivot hole and the other one of the side panels forms a pivot received in the pivot hole.
